(19) United States
(12) Patent Application Publication
(10) Pub. No.: US 2003/0034535 A1
(43) Pub. Date: Feb. 20, 2003

(54) Mems devices suitable for integration with chip having integrated silicon and compound semiconductor devices, and methods for fabricating such devices

(75) Inventors: Barbara Foley Barenburg, Gilbert, AZ (US); Jonathan F. Gorrell, Pompano Beach, FL (US); Kenneth D. Cornett, Coral Springs, FL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/929,020

(22) Filed: Aug. 15, 2001

(51) Int. Cl. H01L 29/82

(52) U.S. Cl. 257/415; 257/417

(57) ABSTRACT

High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include utilizing surfactant enhanced epitaxy, epitaxial growth of single crystal silicon onto single crystal oxide, and epitaxial growth of Zintl phase materials.

### FIELD OF THE INVENTION

This invention relates generally to microelectromechanical devices, and to methods for their fabrication. More specifically, this invention relates to microelectromechanical devices that are suited to integration with both silicon and compound semiconductor devices.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

Traditionally integrated circuits intended for different applications use different material systems. For example integrated circuits used for high frequency signal processing are typically fabricated in Gallium arsenide (GaAs), whereas, logic circuits are commonly fabricated in silicon. Recently an interest has been expressed in building so called ‘systems-on-a-chip’ on a single die. Such a system, as envisioned, would include computing, communication, and sensor systems all integrated on a single chip. Integrating all the electronics for a system-on-a-chip without compromising functionality would require a chip that includes multiple materials (e.g. silicon and GaAs).

Beyond electronic components that a designer may want to include in a system-on-a-chip, other components may be opto-mechanical or electromechanical in nature. For example typical wireless communication devices include quartz crystal resonators. It would be desirable to provide a MEMS equivalent of optomechanical and electromechanical components (e.g., the quartz crystal resonator) that can be integrated with multiple semiconductor materials

What is needed is a chip that incorporates devices made out of plural semiconductor materials (e.g., silicon and GaAs) and MEMS devices.

What is needed is a MEMS device that is suitable for integration in a chip that includes multiple semiconductor materials.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIGS. 21-23 illustrate schematically, in cross section, the formation of a yet another embodiment of a device structure in accordance with the invention;

FIGS. 24, 25 illustrate schematically, in cross section, device structures that can be used in accordance with various embodiments of the invention.

FIGS. 26-30 include illustrations of cross-sectional views of a portion of an integrated circuit that includes a compound semiconductor portion, a bipolar portion, and an MOS portion in accordance with what is shown herein.

FIGS. 31-37 include illustrations of cross-sectional views of a portion of another integrated circuit that includes a semiconductor laser and a MOS transistor in accordance with what is shown herein.

FIGS. 38-49 include cross-sectional elevations views at a sequence of stages in a process for manufacturing a MEMS device that starts with a semiconductor structure similar to that shown in FIG. 1.

FIGS. 50-51 is a flow chart of the process illustrated in FIGS. 38-49.

FIG. 52 is a flow chart of a process for poling a piezoelectric device.

FIG. 53 is a schematic illustration of an oscillator that includes a resonator fabricated by the process that is illustrated with reference to FIGS. 38-49.

FIG. 54 is a plan view of a vertical motion actuator.

FIG. 55 is a sectional elevation view of the actuator shown in FIG. 54.

FIG. 56 is a sectional elevation view of the actuators shown in FIG. 54 with its cantilevered arm in an upwardly deflected state.

FIG. 57 is a flow chart of a process for making the vertical motion actuator shown in FIG. 54.

FIG. 58 is a sectional elevation view of an in-plane actuator. FIG. 59 is a plan view of the actuator shown in FIG. 58. FIG. 60 is a flow chart of a process for making the actuator shown in FIGS. 58-59.

FIG. 61 is a sectional elevation view of a tunable mirror.

FIG. 62 is a plan view of the tunable mirror shown in FIG. 61.

FIG. 63 is a flow chart of a method of fabricating the tunable mirror shown in FIGS. 61-62.

FIG. 64 is a sectional elevation view of a second tunable mirror.

FIG. 65 shows a Michelson interferometer system in which the second tunable mirror shown in FIG. 64. is used.

FIG. 66 is a perspective view of a third tunable mirror.

FIG. 67 is a perspective view of the third tunable mirror shown in FIG. 66 in a deflected state.

FIG. 68 is a perspective view of a surface acoustic wave device.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Monocrystalline group IV materials have a diamond lattice crystal structure. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GalnAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

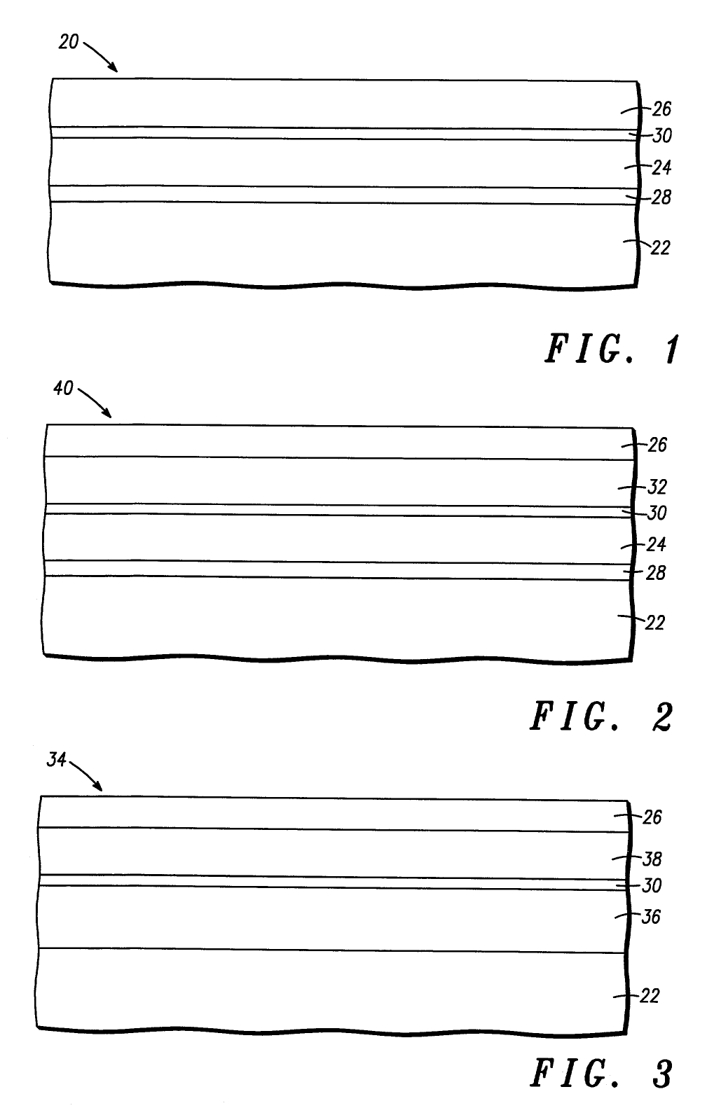

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure. An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGalnAsP), having a thickness of about 1.0 nm to 10 μm. A suitable template for this structure is 1-10 monolayers of zirconium-arsenic (Zr—As), zirconium-phosphorus (Zr—), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2 In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

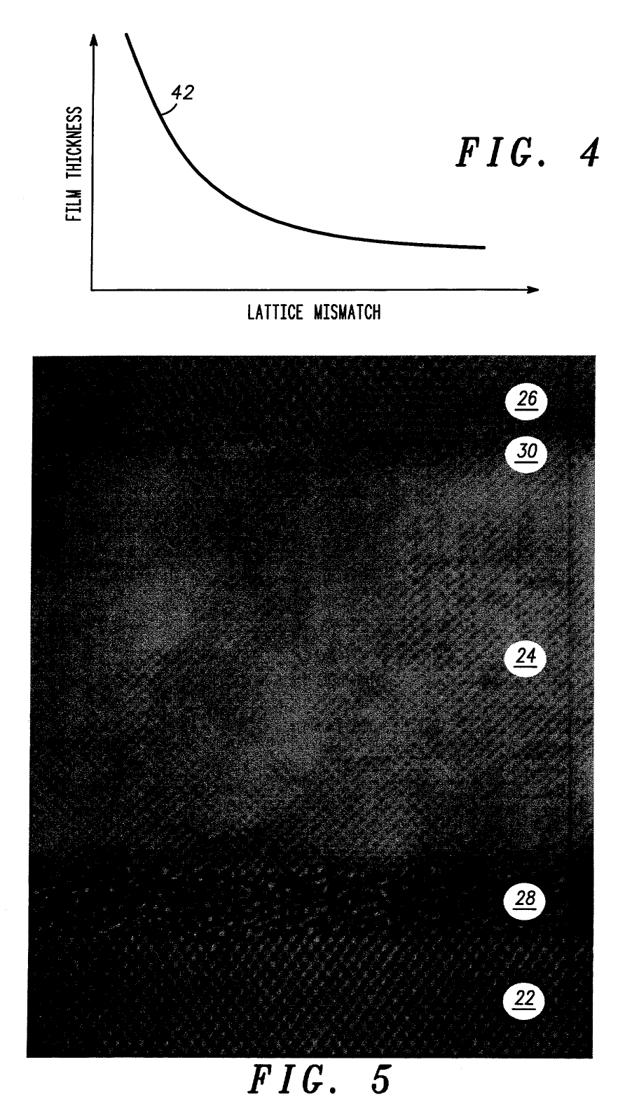

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or 111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants ran be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

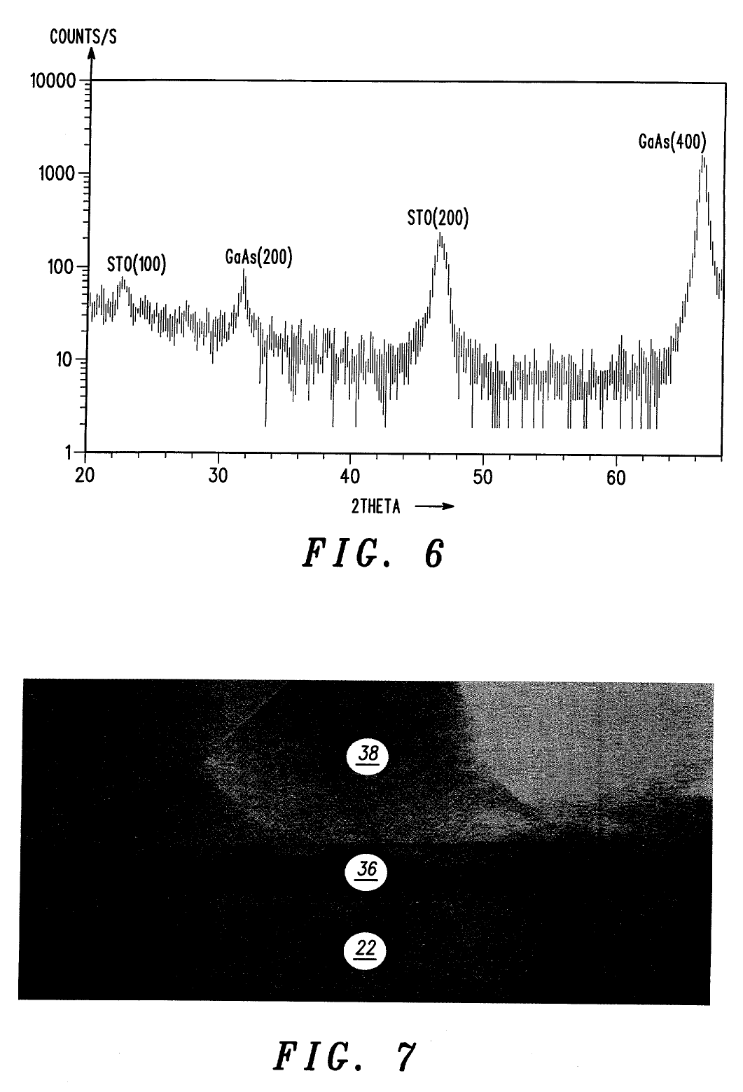

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature about 700° C. to about 1000° C. and a process time of about 5 seconds to about 10 minutes. However, other suitable anneal processes may be employed to convert the accommodating buffer layer to an amorphous layer in accordance with the present Invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

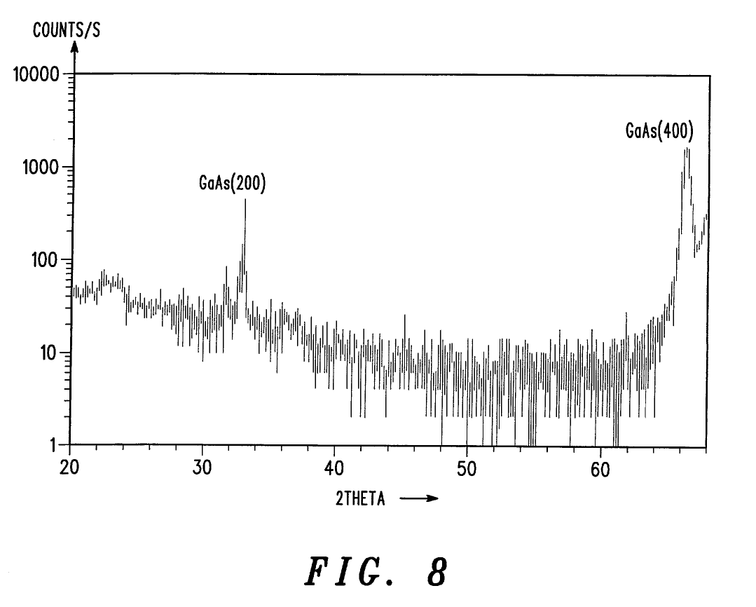

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical Vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

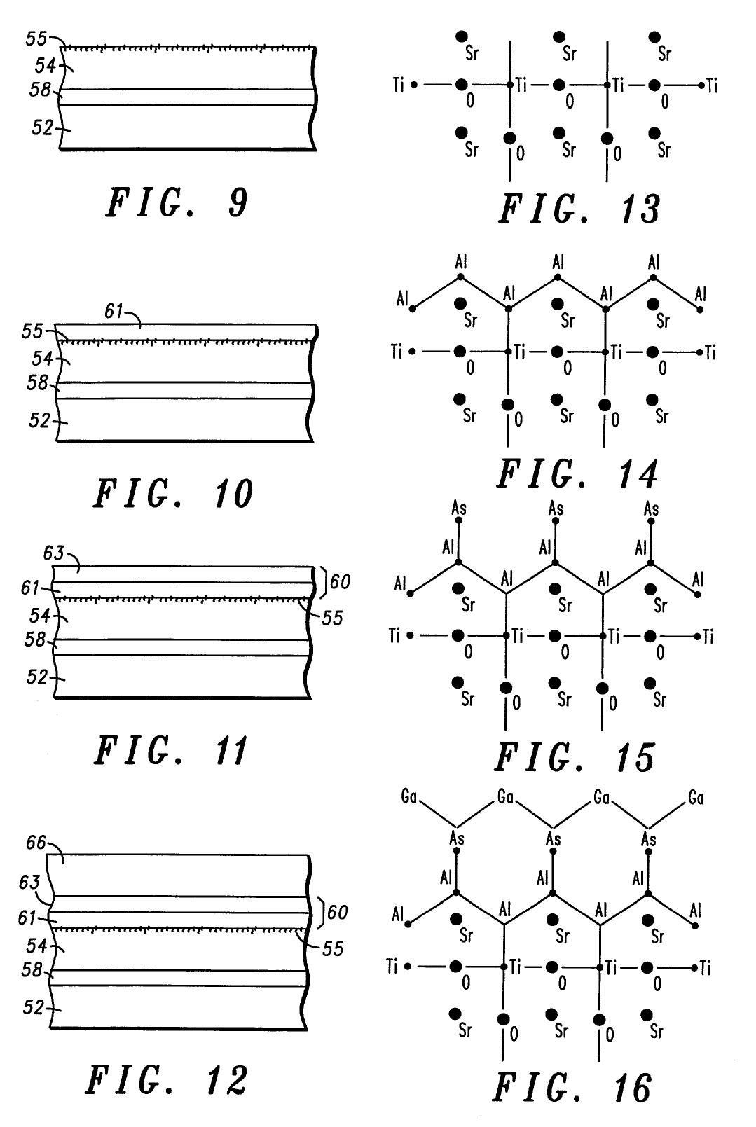

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in Compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semicondcutor material for device formation. More specifically, the deposition of GaN and GaN based systems such as GalnN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

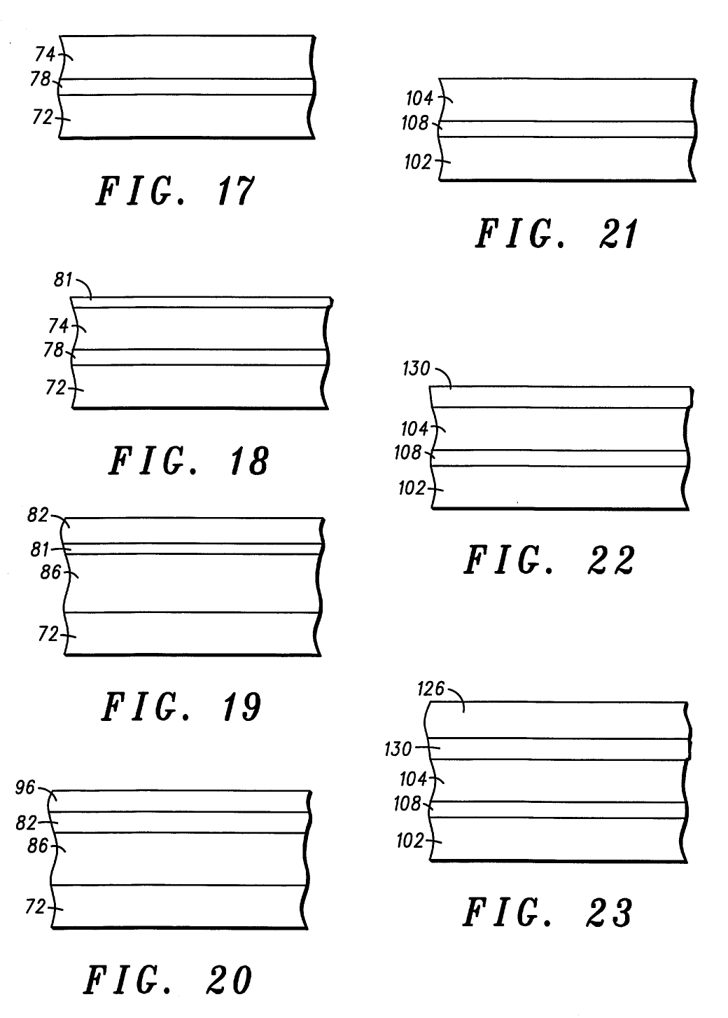

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

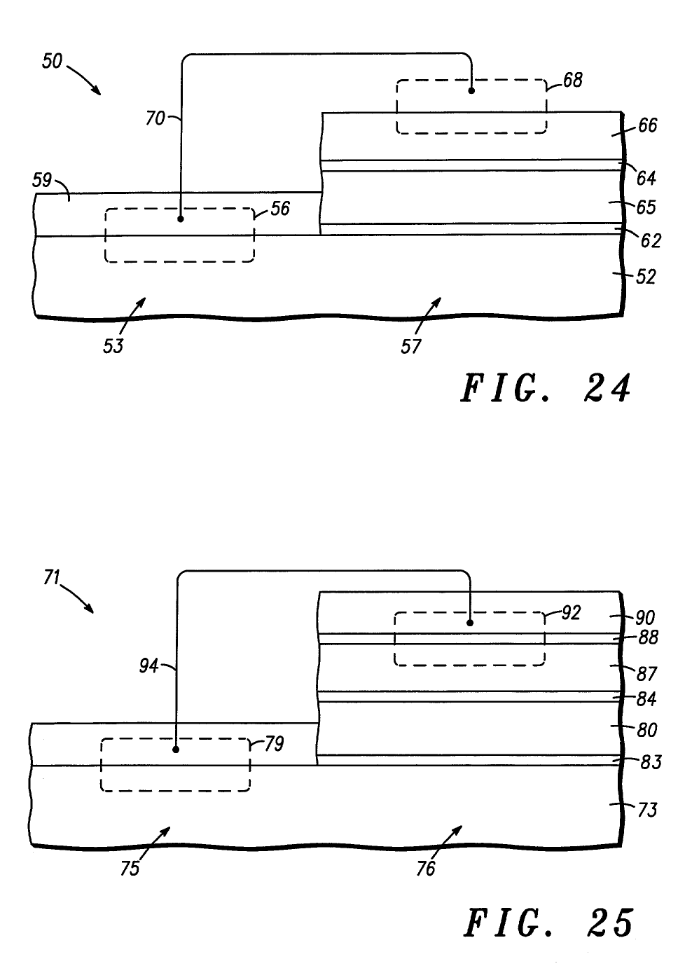

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer 60. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

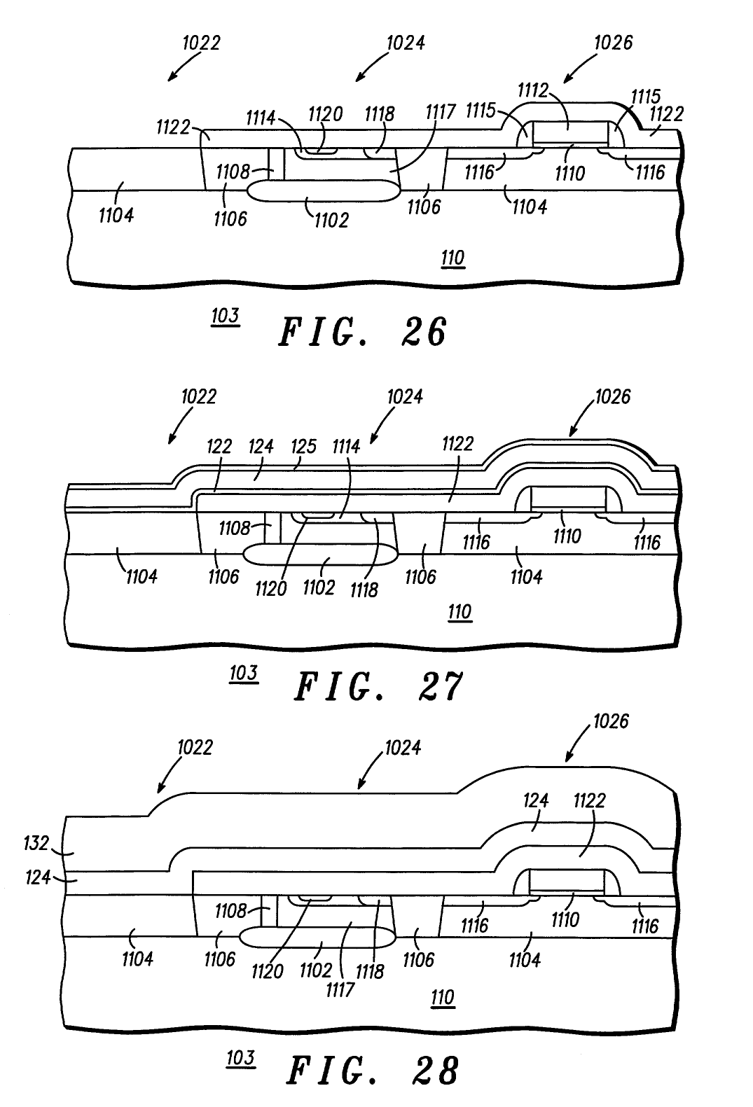

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

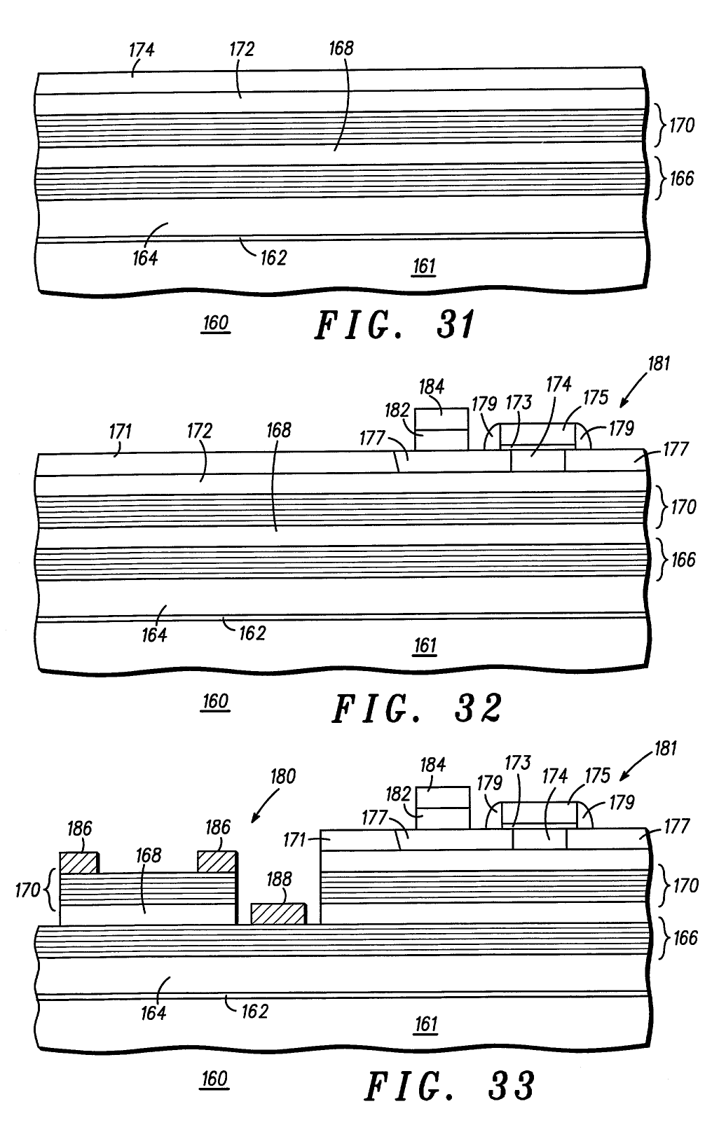

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

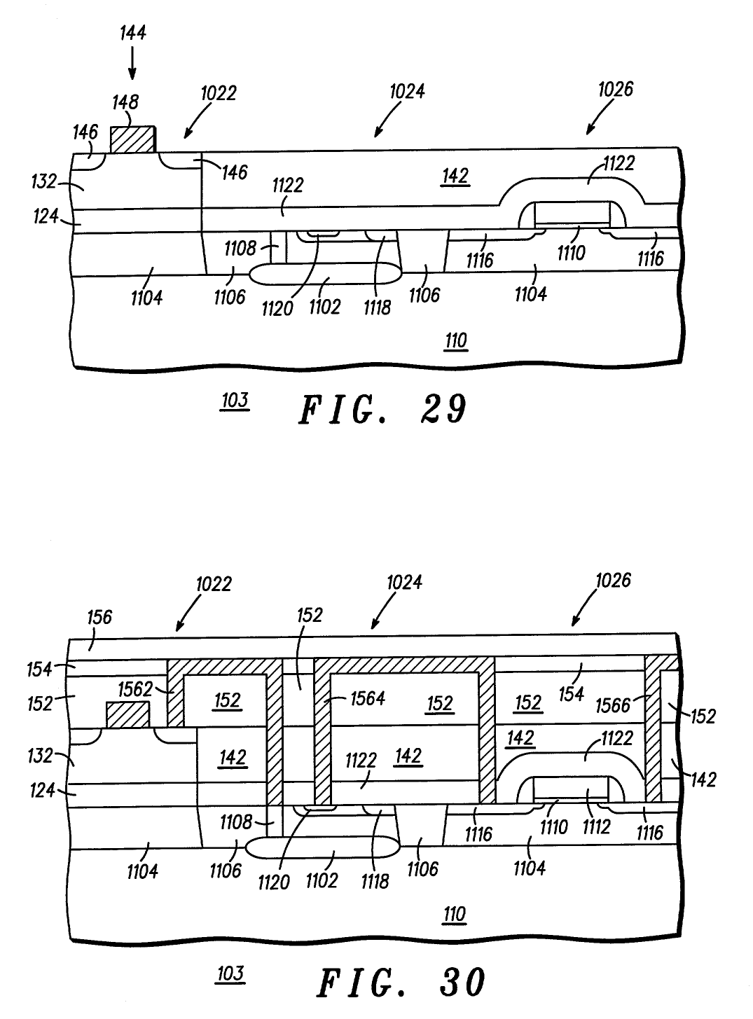

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

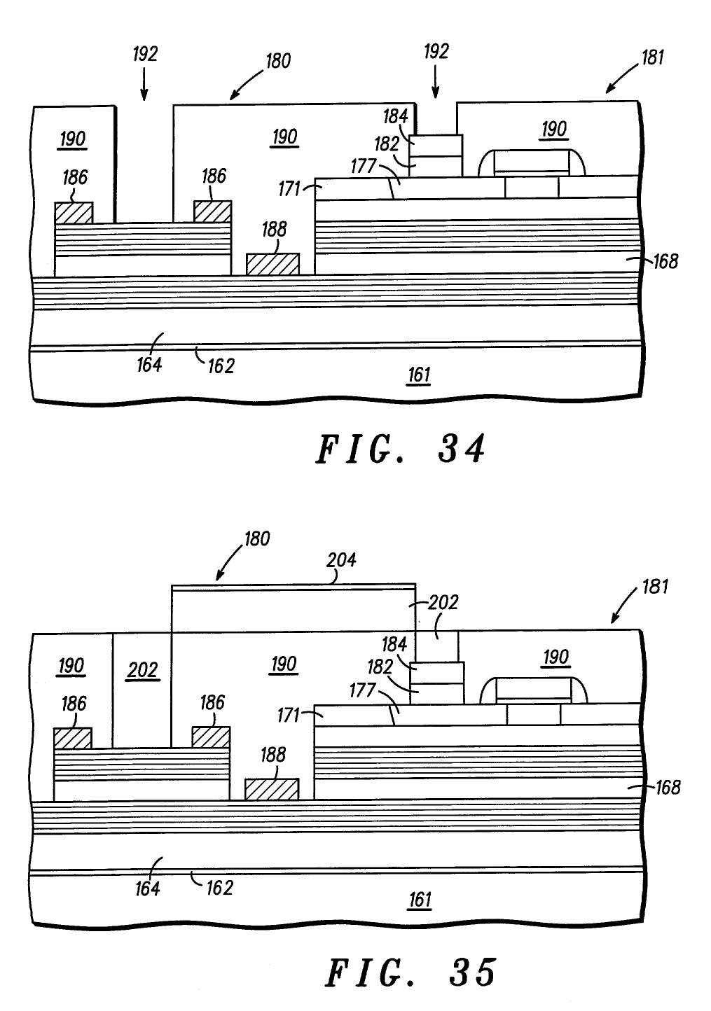

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

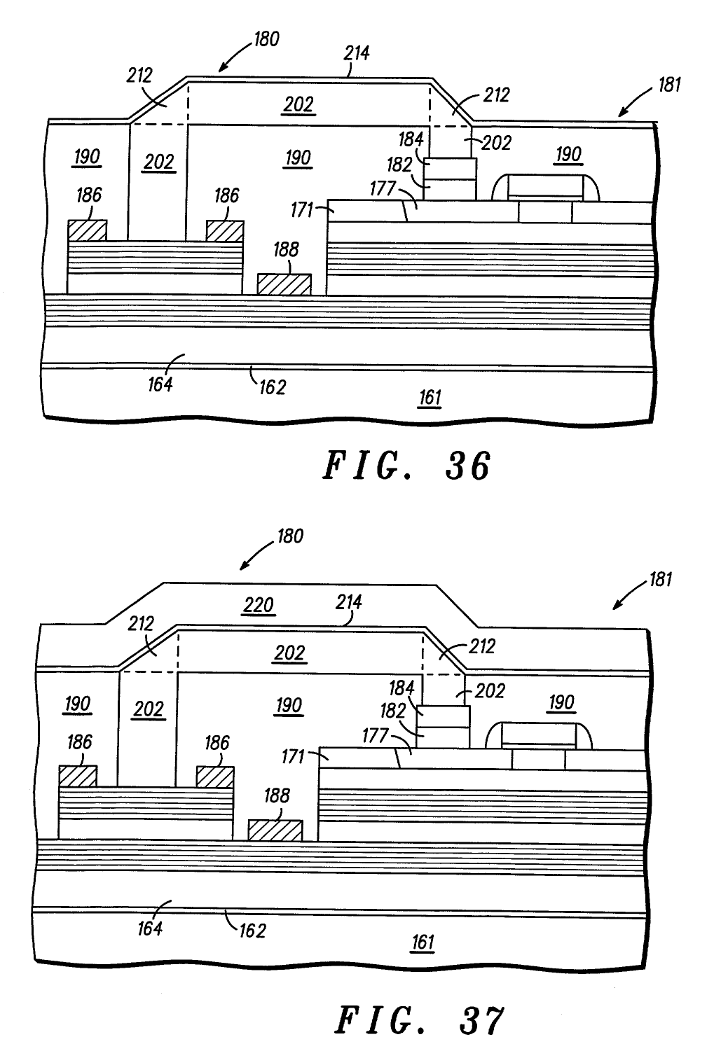

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

According to other embodiments of the invention that are described herein below microelectromechanical system (MEMS) devices are integrated into composite semiconductor structures. Systems fabricated in accordance with the teachings of the present invention can for example comprise devices fabricated in silicon, devices fabricated in GaAs or other compound semiconductor materials, and MEMS devices all fabricated on a single die. According to embodiments described below, an accommodating buffer layer is piezoelectric or can be made piezoelectric by applying a polarizing electric field. Such an accommodating buffer layer in addition to serving the functions described above is used to fabricate piezoelectric electromechanical transducer. Other device layers e.g., the monocrystalline material layer 26 (FIG. 1), or the monocrystalline substrate 22 (FIG. 1) are used to fabricate other parts of the MEMS device.

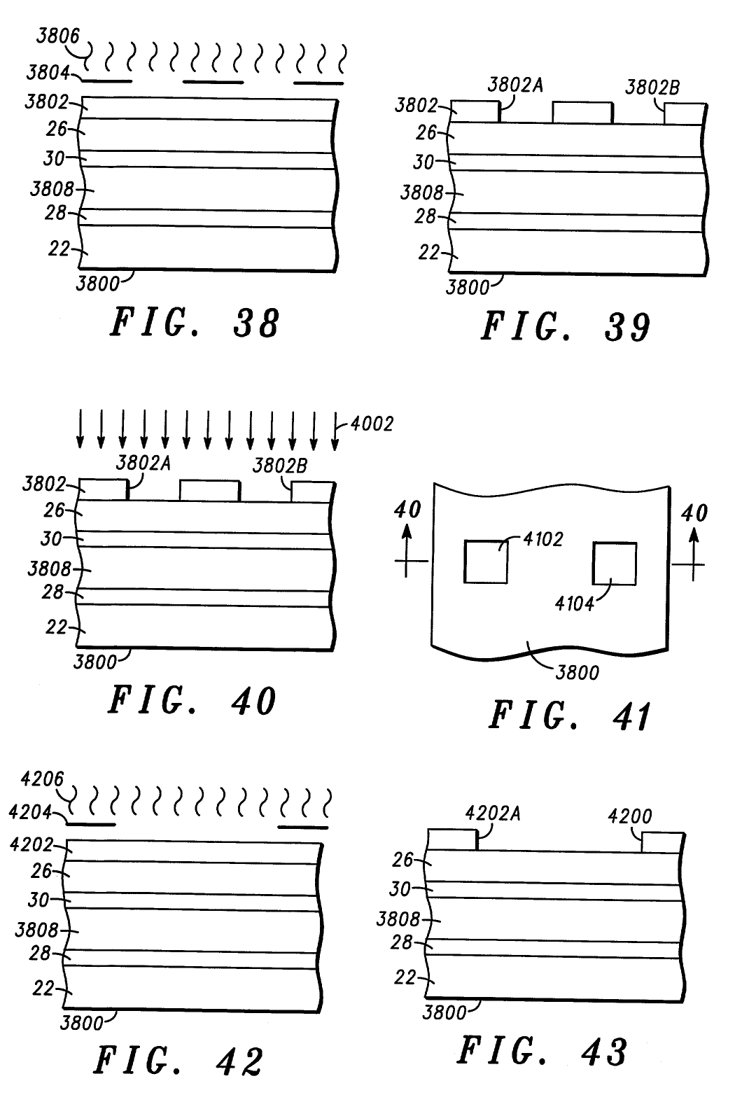

FIGS. 38-49 include cross-sectional elevations views at a sequence of stages in a process for manufacturing a MEMS device. The illustrated process starts with a semiconductor structure 3800 that is similar to that FIG. 1, but has a piezoelectric accommodating buffer layer 3808 (FIG. 38). The semiconductor structure 3800 preferably takes the form of a wafer that is diced into chips near the end of the fabrication process.

The process will be described with reference to FIGS. 50-51 which show a process flow chart and with references to FIGS. 38-49.

In process block 5002 a semiconductor structure 3800 that includes the monocrystalline material layer 26 overlying a piezoelectrically active accommodating buffer layer 3808, which in turn overlies a monocrystalline substrate 22 is obtained. The piezoelectrically active accommodating buffer layer is preferably selected from the group consisting of alkaline earth titanates, zirconates, hafnates, niobates, tantalates, and the tin-based perovskites.

The semiconductor structure 3800 can be obtained by the processes described above in connection with FIGS. 1-23 and variants thereof. Preferably, as shown in FIG. 38 the semiconductor structure 3800 also includes the amorphous intermediate layer 28 interposed between the monocrystalline substrate 22 and the piezoelectrically active accommodating buffer layer 3808.

In process block 5004 a first resist 3802 is applied to the semiconductor structure 3800. In process block 5006, the first resist 3802 is image wise exposed to define a doping pattern.

FIG. 38 is a fragmentary sectional elevation view of semiconductor structure 3800 bearing the first resist 3802 as it is being imagewise exposed to radiant (e.g., ultraviolet, x-ray) or corpuscular (e.g., electron beam) energy 3806 through a first lithography mask 3804.

In process block 5008 the first resist is developed. FIG. 39 is a fragmentary sectional elevation view showing the first resist 3802 in a developed state. The first resist 3802 now has a first edge wall 3802A bounding a first opening and a second edge wall 3802B bounding a second opening.

In process block 5010 the monocrystalline material layer 26 is doped to prepare ohmic contact regions 4102, 4104 (FIG. 41). FIG. 40 is a fragmentary sectional elevation view showing a flux of dopant species 4002 directed at the semiconductor structure 3800 bearing the developed resist 3800. Doping is preferably carried out using an ion implanter.

FIG. 41 is a broken out plan view of the semiconductor structure 3800 showing a first doped region 4102 in spaced relation to a second doped region 4104. The section plane corresponding to FIGS. 38-40 is indicated on FIG. 41.

In process block 5012, after the first resist 3802 has been removed, a second resist 4202 (FIG. 42) is applied to the semiconductor structure 3800. In process block 5014 the second resist 4202 is imagewise exposed to radiant or corpuscular energy 4206 (FIG. 42) through a second lithography mask 4204 (FIG. 42).

FIG. 42 is a fragmentary sectional elevation view of the semiconductor structure 3800 bearing a second resist 4202 undergoing a second imagewise exposure step. In process block 5012, after the first resist has been removed, a second resist 4202 is applied to the semiconductor structure 3800. In process block 5014 the second resist 4202 is imagewise exposed to radiant or corpuscular energy 4206 through a second lithography mask 4204.

In process block 5016 the second resist 4202 is developed. FIG. 43 is a fragmentary sectional elevation view of the semiconductor structure 3800 that shows the second resist 4202 after development. As shown in FIG. 43, an edge wall 4202A bounds a first opening through the second resist 4202. Although not visible in this sectional elevation view, there is preferably another opening through second resist 4202 that is displaced from the above mentioned opening perpendicularly to the plane of the FIG. 43.

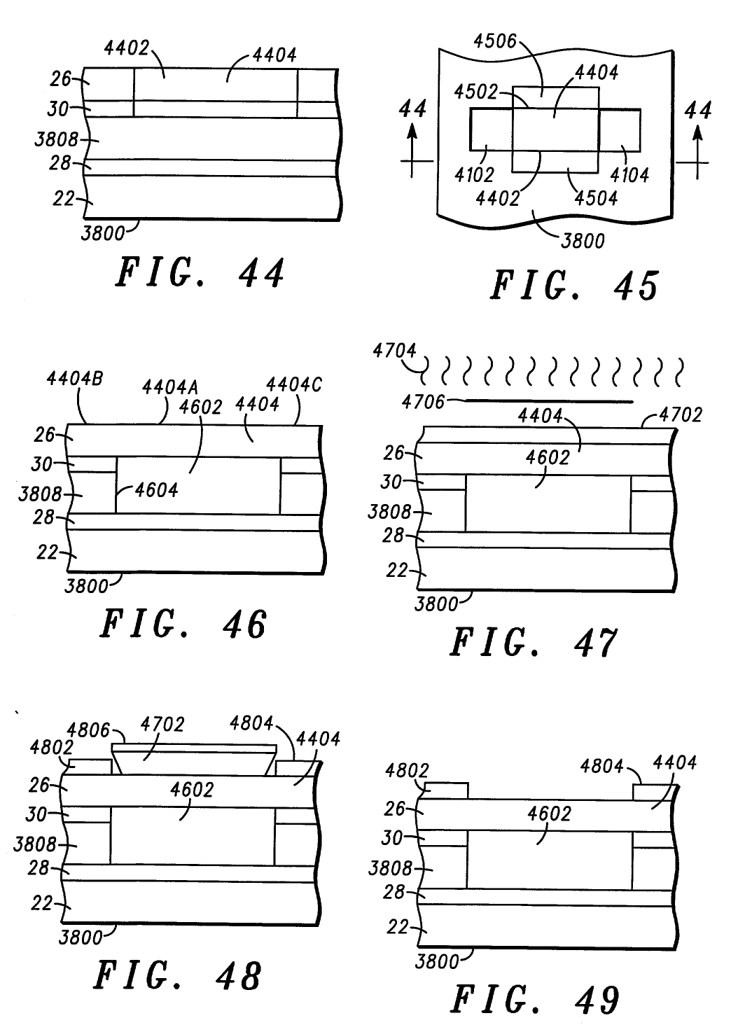

In process block 5018 two elongated openings 4504, 4506 are etched in the monocrystalline material layer 26 using the second resist 4200. The etching step 5018 defines side boundaries 4402 (FIGS. 44, 45), and 4502 (FIG. 45) of a beam 4404 (FIGS. 44, 45).

FIG. 44 is a fragmentary sectional elevation view of the semiconductor structure 3800 after etching step 5018 and FIG. 45 is a fragmentary plan view of the semiconductor structure 3800 after etching process block 5018.

In process block 5020 the piezoelectrically active accommodating buffer layer 3808 is etched out from under the beam 4404. An isotropic etchant that enters the area under beam 4404 through the elongated openings 4504, 4506 is used. A liquid or vapor etchant is useful for step 5020. For example a Hydrofluoric (HF) buffered oxide etch can be used for in process block 5020.

FIG. 46 is a fragmentary sectional elevation view of the semiconductor structure 3800 after the step 5020 of etching the piezoelectrically active buffer layer 3808 under the beam 4404. As shown in FIG. 46, there is a gap 4602 in the piezoelectrically active buffer layer 3808 that is bounded by a closed edge surface 4604 underneath the beam 4404. The presence of the space 4602 under the beam 4404 reduces a mechanical constraint on the beam 4404. One effect of the reduced mechanical constraint is that the beam 4404 can vibrate in a flexural beam mode in which parts of the beam 4404 oscillate vertically. Flexural vibration of the beam 4404 is useful if the beam is used as a frequency selective resonator. The presence of the space 4602 also creates region that under the beam 4404 that has an index of refraction of unity. The index of refraction of unity is of consequence if the beam 4404 is used in an optical MEMS device such as described in more detail below.

Referring again to FIG. 50, in process block 5022, after removing the second resist 4202 (FIGS. 42-43), a third resist 4702 is applied to the semiconductor structure 3808. In process block 5024, the third resist 4702 is imagewise exposed to define an outline of electrodes in the form of electrical contacts 4802, 4804 on the monocrystalline material layer 26. Metal traces used to connect the device being fabricated to an external circuit can also be formed at this time. Alternatively connections to an external circuit can be formed during subsequent steps. In process block 5026, the third resist 4702 is developed

FIG. 47 is a fragmentary sectional elevation view of the semiconductor structure 3800 bearing the third resist 4702 as it is being imagewise exposed to corpuscular or radiant energy 4704 through a third lithography mask 4706.

Referring to FIG. 51, in process block 5102, a metal film is deposited on semiconductor structure 3802 covering the monocrystalline material layer 26 in areas not covered by the third resist 4702.

FIG. 48 is a fragmentary sectional elevation view of the semiconductor structure 3800 showing a deposited metal film that includes first and second electrical contacts 4802 and 4804 overlying the doped regions 4102, 4104 (FIGS. 41, 45) respectively, and a patch 4806 of deposited metal overlying the third resist 4702. In process block 5104 the third resist 4702 (FIG. 47) is removed taking the patch 4806 of metal with it. The foregoing process of depositing metal is known as a lift-off process. The two contacts are used to apply an electric field to the piezoelectrically active accommodating buffer layer 3808 in order to electrically induce vertical mechanical motion of the beam 4404 or to receive an electrical signal caused by the mechanical deformation of the beam 4404. Portions of the piezoelectrically active accommodating buffer layer 3808 underlying the first 4802 and second 4804 electrical contact serve as piezoelectric transducers.

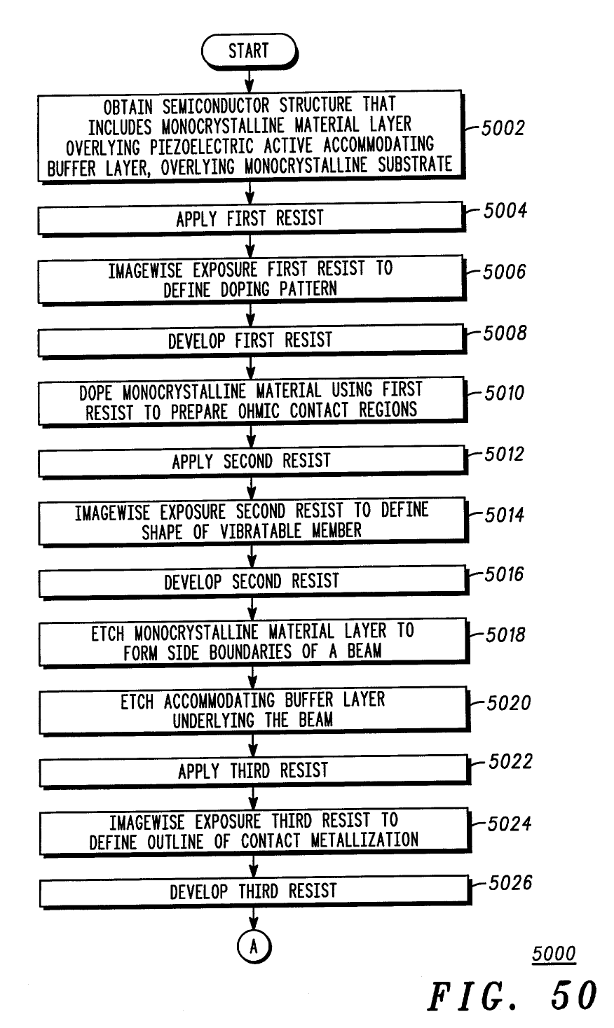

FIG. 49 is a sectional elevation view of the semiconductor structure 3800 after removal of the third resist 4702.

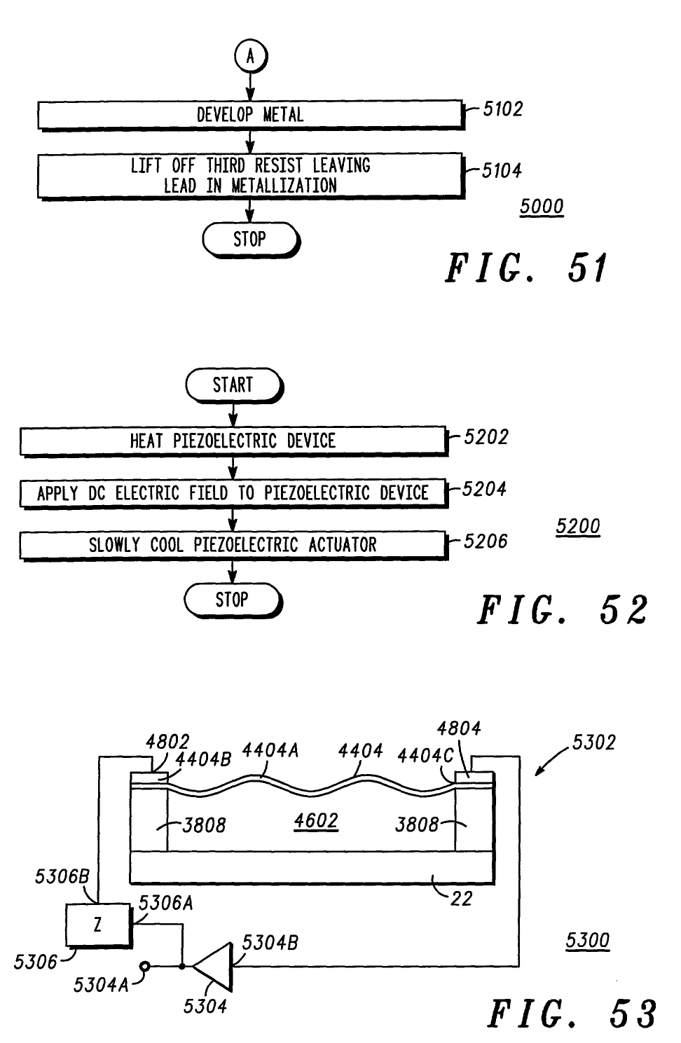

Piezoelectric materials used in piezoelectric devices must be poled. During poling filed domains within the piezoelectric material are aligned. After poling, the piezoelectric material will exhibit the piezoelectric effect. A method of poling a piezoelectric material, according to an embodiment of the invention is illustrated in FIG. 52. FIG. 52 is a flow chart 5200 of a process for poling a piezoelectric device. In process block 5202, a piezoelectric device (e.g. semiconductor structure 3800) is heated. Preferably, the piezoelectric device is heated to the Curie temperature. In process block 5204 a DC electric field is applied to the piezoelectric device, and in process block 5206 the piezoelectric device is allowed to cool while the electric field is maintained. This and other methods of poling piezoelectric devices are well known to one of ordinary skill in the art.

For polarizing the semiconductor structure 3800, the electric field used for polarizing is preferably oriented vertically, in order to obtain a vertically oriented polarization vector within the piezoelectrically active accommodating buffer layer 3800.

FIG. 53 is a schematic illustration of an oscillator 5300 that includes a resonator 5302 fabricated by the process that is illustrated with reference to FIGS. 38-49.

The resonator 5302 comprises the beam 4404, piezoelectrically active accommodating buffer layer 3808, and electrical contacts 4804 supported on the monocrystalline substrate 22. The beam 4404 includes a first end 4404B overlying the piezoelectrically active accommodating buffer layer 3808, and underlying the first electrical contact 4802, and a second end 4404C overlying the piezoelectrically active accommodating buffer layer 3808, and underlying the second electrical contact 4804. A mid section 4404A of the beam 4404 overlies the gap 4602 in the piezoelectrically active accommodating buffer layer 3808.

Remaining parts of the oscillator 5300 include an amplifier 5304, and an impedance device 5306. The amplifier 5304 includes an input 5304B electrically coupled to the second electrical contact 4804 which overlies the second end 4404C of the beam 4404, and an output 5304A electrically coupled to an input 5306A of the impedance device 5306. The impedance device further comprises an output 5306B electrically coupled to the first electrical contact 4802 that overlies the first end 4404B of the beam 4404.

In operation, a signal output by the amplifier 5304 is attenuated by the impedance device 5306, and coupled to the first electrical contact 4802. The signal produces an electric field within piezoelectrically active accommodating buffer layer 3808 underlying the first electrical contact 4802. The signal causes the piezoelectrically active accommodating buffer layer 3808 underlying the first electrical contact 4802 to expand and contract in an oscillatory fashion. The oscillation of piezoelectrically active accommodating buffer layer 3808 underlying the first electrical contact 4802 drives a flexural beam mode of oscillation in the beam 4404. The beam 4404 is dimensioned to oscillate at a predetermined frequency. For example a frequency used in a communication system for which the oscillator 5300 serves as a reference frequency source. The oscillation of the beam 4404 exerts a periodic stress on a portion of the piezoelectrically active accommodating buffer layer 3808 underlying the second electrical contact 4804 and the second end 4404C of the beam 4404. The frequency of the stress is equal to the frequency of oscillation of the beam 4404. Due to the piezoelectric effect, the period stress causes a periodic voltage at the same frequency to appear on the second contact 4804. The periodic voltage appearing on the second electrical contact 4804 is coupled to the input 5204B of the amplifier 5204. The periodic voltage serves as positive feedback, causing the oscillator 5300 to oscillate. The gain of the amplifier 5304 and the impedance of the impedance device 5306 are selected to achieve oscillation.

MEMS devices are usually fabricated on wafers (e.g. a wafer having the structure of semiconductor structure 3800 (FIG. 38). A natural coordinate system for a wafer is one in which the Z axis is perpendicular to the plane of the wafer. A distinction can be made between actuators that generate movement in the plane of the wafer, and those that generate movement perpendicular (along the Z axis) to the plane of the wafer.

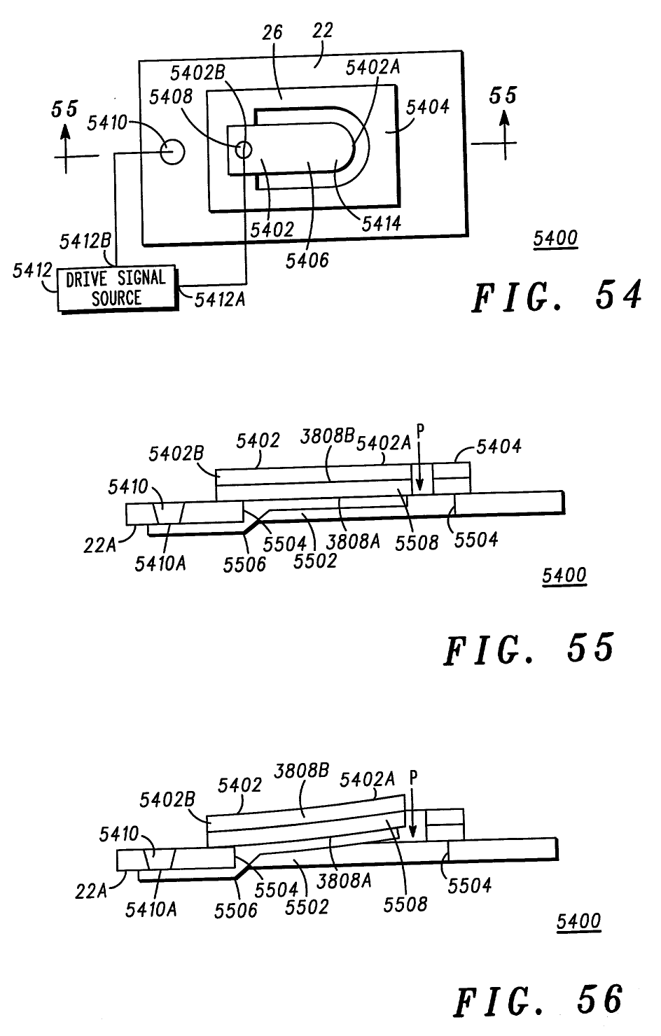

FIGS. 54-57 relate to a MEMS actuator 5400 that is fabricated from semiconductor structure 3800 and is capable of generating movement perpendicular to the planes of the layers of semiconductor structure 3800.

Referring to FIG. 54, a plan view of a vertical motion actuator 5400 is shown. The vertical motion actuator 5400 includes a cantilevered arm 5402 that includes a free end 5402A and a clamped end 5402B. The clamped end 5402B of the cantilevered arm 5402 is joined to a perimeter ring 5404. The cantilevered arm 5402 includes an upper part 5414 made out of the monocrystalline material layer 26 (FIG. 1), and a lower piezoelectrically active part (FIG. 55) made out of the piezoelectrically active accommodating buffer layer 3808 (FIG. 38). The piezoelectrically active part 5508 serves as a piezoelectric transducer. The cantilevered arm 5402 and the perimeter ring 5404 are formed by etching through the monocrystalline material layer 26, and the piezoelectrically active accommodating buffer layer 3808 layer. The cantilevered arm 5402 and the perimeter ring 5404 are supported on the monocrystalline substrate 22 (FIG. 1). The monocrystalline material layer 26 is doped to create a doped region 5406 that covers the cantilevered beam 5402 and extends onto the perimeter ring 5404 adjacent the clamped end 5402B of the cantilevered arm 5402. An ohmic contact 5408 is located on the portion of the doped region located on the perimeter ring. A via 5410 extends though the monocrystalline substrate 22.

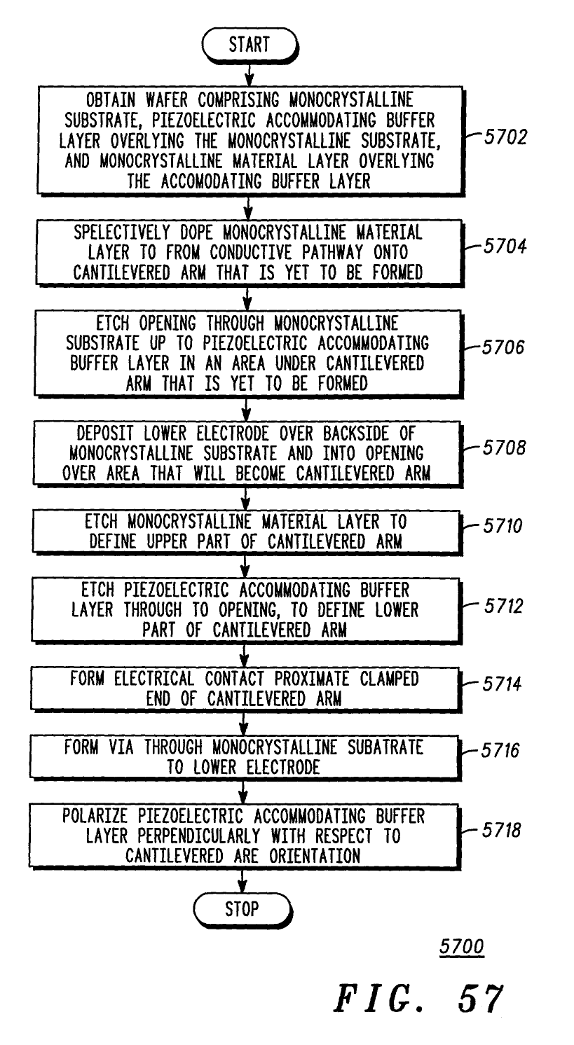

Referring to FIG. 55 a sectional elevation view of the vertical motion actuator 5400 is shown. The section plane corresponding to FIG. 55 is indicated on FIG. 54. As shown in FIG. 55 there is an opening 5502 through the monocrystalline substrate 22 underneath the cantilevered arm 5402. The opening 5502 is bounded by a closed curve edge 5504 (seen here in section) of the monocrystalline substrate 22. A lower electrode 5506 extends from an exit point 5410A of the via 5410 on the lower face 22A of the monocrystalline substrate 22, over the lower face 22A of the monocrystalline substrate 22 into the opening 5502 in the monocrystalline substrate 22, and onto a lower face 3808A of the lower piezoelectrically active part 5508 of the cantilevered arm 5402. The lower electrode 5506 and the doped region 5408 of the monocrystalline material layer 26 are used to apply an electric field to the lower piezoelectrically active part 5508 of the cantilevered arm, in order to induce piezoelectric action. The applied electric field will be oriented perpendicular to the interface between the upper part 5414 and lower piezoelectrically active part 5508 of the cantilevered arm 5402. The lower piezoelectrically active 5508 part is also polarized perpendicular to the interface. The polarization vector is identified by the letter P in FIGS. 55-56. An upper face 3808B of the lower piezoelectrically active 5508 part of the cantilevered arm 5402 is adjacent the upper part 5414 of the cantilevered arm 5402.

A drive signal source 5412 includes a first output 5412A electrically coupled to the ohmic contact 5408 and a second output 5412B electrically coupled to the via 5410. The electric coupling to the signal source preferably comprise metal traces (not shown). A signal generated by the drive signal source 5412 produces an electric field across the lower piezoelectrically active part 5508 of the cantilevered arm 5402. When the applied electric field is parallel to the polarization of the lower piezoelectrically active part 5508, the thickness of the lower part 5508 (i.e. its dimension parallel to the applied field) tends to increase. At the same time its length (i.e. the dimension parallel to the longitudinal axis of the cantilevered arm 5402) tends to decrease. Because the lower part 5508 is attached to the upper part 5414, the length of which is not effected by the applied field, conflicting stresses in the upper 5414 and lower 5508 parts will occur. An equilibrium between these forces will occur when the cantilevered arm 5402 curls downward. On the other hand when the applied electric field is anti-parallel to the polarization of the lower part 5508, then the thickness of the lower part 5508 will tend to decrease, and its length to increase. This also results in conflicting stresses between the lower part 5508 and upper part 5414 of the cantilevered arm 5402 that are, in this case, equilibrated when the cantilevered arm assumes an upwardly curved profile as shown in FIG. 56. By controlling the magnitude of the electric field applied to the lower piezoelectrically active part 5508 of the cantilevered arm 5402 its curvature can be controlled.

Thus, the by adjusting the voltage output by the drive signal source 5412, the vertical displacement of the free end 5402A of the cantilevered arm 5402 can be controlled.

The vertical displacement actuator 5400 can be used as an optomechanical switch that selectively blocks the path a laser beam. Alternatively the vertical displacement actuator 5400 can be used for adjusting the position of a fine tipped probe used in a Scanning Tunneling Microscope (STM) or Atomic Force Microscope (AFM).

FIG. 57 is a flow chart of a process 5700 for making the vertical motion actuator 5400. The process 5700 can start with the semiconductor structure 3800 illustrated in FIG. 38.

In process block 5702 a wafer comprising a monocrystalline substrate 22 (FIG. 1), a piezoelectric accommodating buffer layer 3800 (FIG. 38) overlying the monocrystalline substrate 22, and a monocrystalline material layer 26 (FIG. 1) overlying the accommodating buffer layer 3800 is obtained. The wafer obtained in step 5702 can have a structure such as described above with reference to FIGS. 1-23, 38 and be manufactured by the processes described in connection with those FIGS. In process block 5704 the monocrystalline material layer 26 is doped to form a conductive pathway (doped region 5408) onto a cantilevered arm 5402 (which at this point in the process is yet to formed). In process block 5706 the opening 5502 is etched through the monocrystalline substrate 26 up to the piezoelectrically active accommodating buffer layer 3808 under that area at which the cantilevered arm 5402 will be formed. In process block 5708 the lower electrode 5506 is deposited over the backside 22A of the monocrystalline substrate 22 and into the opening 5502 in an area that will become the cantilevered arm 5402. In process block 5710 the monocrystalline material layer 26 is etched to define the upper part 5414 of the cantilevered arm 5402. In process block 5712 the piezoelectrically active accommodating buffer layer 3808 is etched to define the lower part 5508 of the cantilevered arm 5402. In process block 5714 the electrical contact 5408 is formed proximate the clamped end 5402B cantilevered arm 5402. In process block 5716 the via 5410 through the monocrystalline substrate 22 is formed. In process block 5718 the piezoelectric accommodating buffer layer 3808 is polarized.

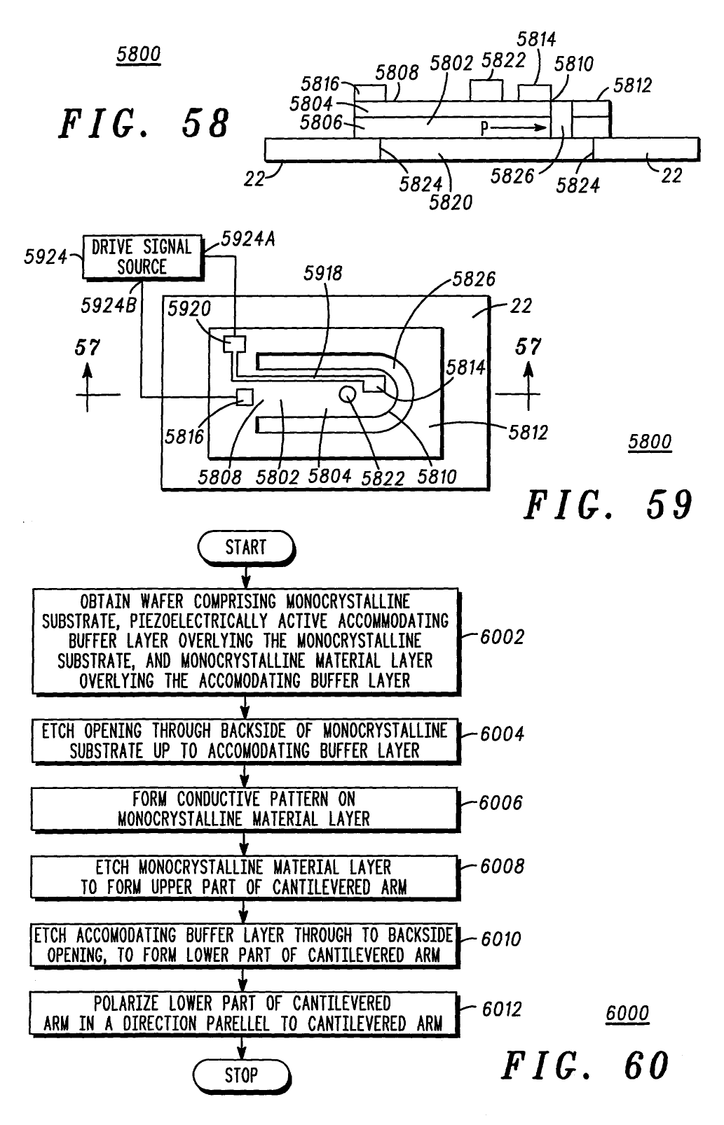

FIGS. 58-60 relate to an in-plane servo actuator that generates motion in the plane of a wafer from which it is fabricated. By ‘in-plane’ it is meant that vectors describing the motion caused by the actuator can be contained in the plane of the semiconductor structure (e.g., the semiconductor structure shown in FIG. 1) from which it is fabricated. This contrasts with the actuator described with reference to FIGS. 54-57 above which caused motion perpendicular to the described plane.

FIG. 58 is a sectional elevation view of an in-plane actuator 5800 and FIG. 59 is a plan view of the actuator 5800. According to this embodiment of the invention, the actuator 5800 is fabricated from the semiconductor structure 3800 shown in FIG. 38. The actuator 5800 comprises a cantilevered arm 5802 that includes an upper part 5804 formed from the monocrystalline material layer 26, and a lower part 5806 formed from the piezoelectrically active accommodating buffer layer 3808. The lower part 5806 serves as a piezoelectric transducer. The cantilevered arm 5802 comprises a clamped end 5808 and a free end 5810. The lower part 5806 of the cantilevered arm 5802 is polarized such that its polarization vector points from the clamped end 5808 to the free end 5810 of the cantilevered arm 5802. The cantilevered arm 5802 is integral with a peripheral ring 5812 to which it is attached at its clamped end 5808. A U-shaped 5826 separates the cantilevered beam 5802 from the peripheral ring 5812 except at the clamped end 5808. The cantilevered arm 5802 and the peripheral ring 5812 are supported on the monocrystalline substrate 22. There is an opening 5820 that is bounded by a closed curve edge 5824 through the monocrystalline substrate 22 below the cantilevered arm 5802. A first electrode 5814 is positioned proximate the free end 5810 of the cantilevered arm 5802, and a second electrode 5816 is positioned on the peripheral ring 5812 proximate the clamped end 5808 of the cantilevered arm 5802. A conductive trace 5918 extends from the first electrode 5814 over the cantilevered arm 5802 to the peripheral ring 5812 where it takes a ninety degree turn and extends to a conductive pad 5920. The first and second electrodes 5814, 5816, conductive trace 5918, and conductive pad 5920 are formed by selectively doping the upper part 5808 the cantilevered arm 5802 and peripheral ring 5812. According to an alternative embodiment, the first and second electrodes 5814, 5816, conductive trace 5918, and conductive pad 5920 are depositing metal. According to another alternative embodiment the upper part 5804 of the cantilevered arm 5802 is eliminated, and the first and second electrodes 5814, 5816, and conductive trace 5918 are formed by depositing metal directly on the lower part 5806 of the cantilevered arm 5802. A device 5822 to be moved by the actuator 5800 is located on the cantilevered arm 5802 towards the free end 5810.

A drive signal source 5924 includes a first output 5924A electrically coupled to the conductive pad 5920, and a second output 5924B electrically coupled to the second electrode 5816. The electrical couplings can comprise interconnects used in the semiconductor fabrication that are well known to one of ordinary skill in the art.

In operation the drive signal source outputs a voltage that appears between the first electrode 5814, and the second electrode 5812. An electric field associated with the voltage passes through the piezoelectrically active lower part 5806 of the cantilevered arm. The electric field causes the distance between the free end 5810 and the clamped end 5808 of the cantilevered arm to either increase or decrease depending on the whether the field is parallel or anti-parallel to the direction of polarization of the lower part 5806 of the cantilevered arm 5802. If the field is parallel to the polarization the length of the cantilevered arm 5802 will increase and if it is anti-parallel the length will decrease. By controlling the polarity and magnitude of the voltage output by the drive signal source 5824 the position of the device 5822 can be adjusted.

FIG. 60 is a flow chart 6000 of a process for making the actuator shown in FIGS 58-59.

In process block 6002 a wafer comprising a monocrystalline substrate 22 (FIG. 1), and a piezoelectrically active accommodating buffer layer 3808 (FIG. 38) overlying the monocrystalline substrate is obtained. Preferably the wafer further comprises a monocrystalline material 26 (FIG. 1) layer overlying the piezoelectrically active accommodating buffer layer 3808.

In process block 6004 an opening is etched in the monocrystalline substrate 22 up to the piezoelectrically active accommodating buffer layer 3808.

In process block 6006 a conductive pattern including electrodes 5814, 5816, conductive trace 5918, and conductive pad 5920 is formed.

In process block 6008 the monocrystalline material layer 26 is etched to form the upper part 5804 (FIG. 58) of the cantilevered arm 5802.

In process block 6010 the accommodating buffer layer 24 is etched though to the opening 5820 in the monocrystalline substrate 20 to form the lower part 5806 (FIG. 58) of the cantilevered arm 5802.

In process block 6012 the lower part 5806 of the cantilevered arm 5802 is polarized to establish a polarization vector aligned with the length of the cantilevered arm 5802.

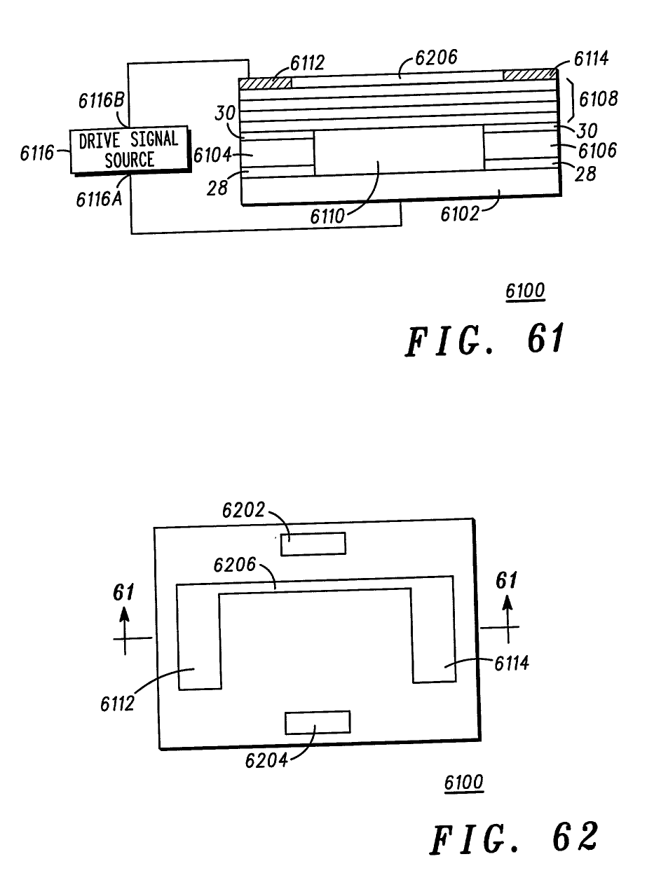

FIG. 61 is a sectional elevation view of a tunable mirror 6100 and FIG. 62 is a plan view of the tunable mirror 6100 shown in FIG. 61. The mirror includes a base 6102 made out of the monocrystalline substrate 22 (FIG. 1). The base serves as a lower optical layer. The base is preferably made out of silicon, which is transparent in the infrared region of the spectrum.

A first piezoelectric pedestal 6104 and a second piezoelectric 6106 pedestal that are fabricated from the piezoelectrically active accommodating buffer layer 3808 (FIG. 38) are located on the base 6102. The first 6104 and second 6106 pedestals serve as piezoelectric transducers. Portions of the amorphous intermediate layer 28 are interposed between the first 6104 and second 6106 piezoelectric pedestals and the base 6102.

An optical multi-layer stack 6108 is supported by the first and second pedestals 6104, 6106. The multi-layer stack 6108 preferably includes alternating layers of Gallium arsenide and Aluminum Gallium arsenide. Portions of the template layer 30 are interposed between the first and second pedestals 6104, 6106 and the multi-layer stack 6108.

A thin air space 6110 is located between the multi-layer stack 6108 and the monocrystalline substrate 22, and between the first 6104 and second 6106 piezoelectric pedestals.

The heights and indexes of refraction of the layers of the multi-layer stack 6108, the thin air space 6110, and the base 6102 effect the magnitude and phase of optical radiation (e.g. infra-red) that is reflected by or transmitted through the tunable mirror 6100.

A first electrode 6112 and a second electrode 6114 are formed on the multi-layer stack 6108 overlying the first and second piezoelectric pedestals 6104, 6106 respectively. The first and second electrodes 6112, 6114 are used to establish a piezoelectric effect inducing electric field in the first 6104 and second 6106 piezoelectric pedestals causing there heights to either increase or decrease depending on the polarity of the field. As the height of the piezoelectric pedestals 6104, 6106 changes so will the height of the air space 6110. A change in the height of the air space 6110 effects the optical properties (e.g., the transmission and reflection coefficients) of the tunable mirror 6100.

A drive signals source 6116 includes a first output 6116A electrically coupled to the base 6102, and a second output 6116B electrically coupled to the first 6112, and second 6114 electrodes. The drive signal source 6116 provides the voltage required to establish the piezoelectric effect inducing electric field.

Tuning of the air space 6110 height can be changed for the purpose of compensating for variations in the optical thickness of the base 6102, shifting the spectral response curve of the tunable mirror 6100 or modulating the amplitude of a reflected or transmitted beam.

The tunable mirror 6100 can be used with a beam incident normally on the multi-layer 6108 or base 6102 or at a non zero angle of incidence.

As seen in FIG. 62 there is a first slot 6202, and a second slot 6204 etched through the multi-layer stack 6108. The first and second slots 6202, 6204 are etched anisotropically, to create openings through which an isotropic etchant can enter in order to etch the accommodating buffer layer 24 and create the air space 6110. Also seen in FIG. 62 is a metal trace 6206 connecting the first and second electrodes 6112, 6114. The section plane corresponding to FIG. 61 is indicated in FIG. 62.

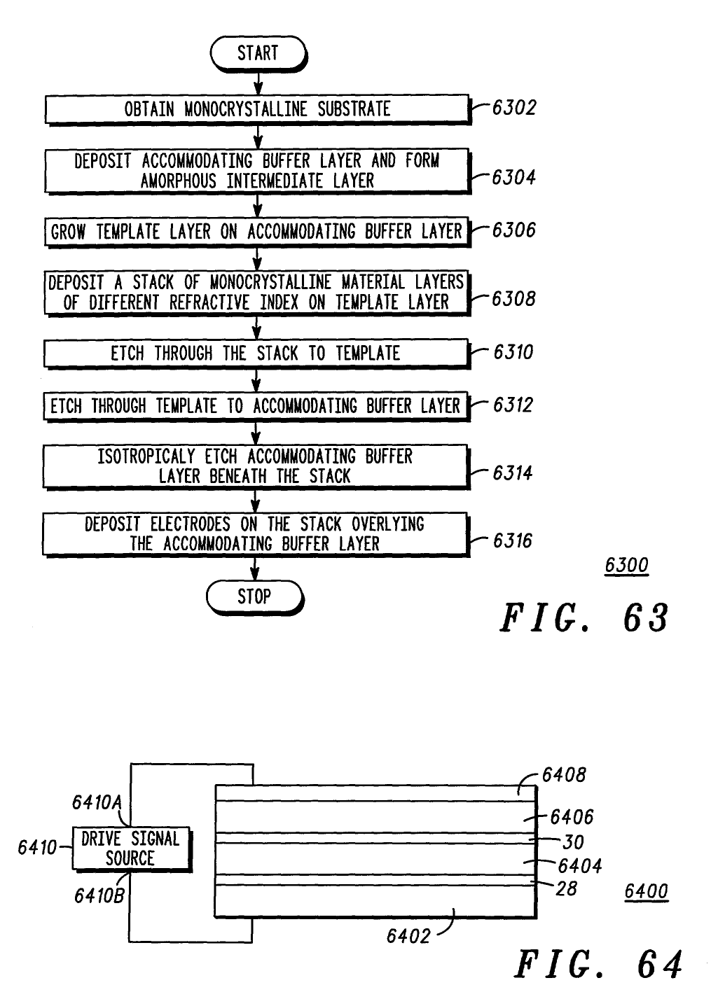

FIG. 63 is a flow chart of a method of fabricating the tunable mirror shown in FIGS. 61-62. In process block 6302 the monocrystalline substrate 22 is obtained. Preferably the monocrystalline substrate comprises a silicon wafer. In process block 6304 a piezoelectrically active accommodating buffer layer 24 is deposited and in the same process the amorphous intermediate layer 28 (preferably silicon di-oxide) is formed.

In process block 6306 the template layer 30 is grown.

In process block 6308 the multi-layer stack 6108 of monocrystalline material layers of different refractive index is grown on the template layer 30.

In process block 6310 the multi-layer stack 6108 and template 30 are etched through to form the first and second slots 6202, 6204 and also preferably to define a peripheral boundary of the tunable mirror 6100.

In process block 6312 the accommodating buffer layer 24 is isotropically etched to create air space 6110. In preparation for process block 6312 a resist is used to prevent the flow of etchant to areas that are not to be etched.

In process block 6314 the first and second electrodes 6112, 6114 are deposited on the multi-layer stack 6108.

FIG. 64 is a sectional elevation view of a second tunable mirror 6400. The second tunable mirror 6400 comprises a base 6402 made out of the monocrystalline substrate 22. Overlying the base 6402 in succession are the amorphous intermediate layer 28, a piezoelectric accommodating buffer layer 6404, the template layer 30, the monocrystalline material layer 26, and a mirror-electrode 6408. Preferably, the layers 28, 6404, 30, 26, 6408 overlying the base 6402 are anisotropically etched to form a mesa on base 6402. The piezoelectric accommodating buffer layer 6404 serves as a piezoelectric transducer. A drive signal source 6410 includes a first output 6410A electrically coupled to the mirror-electrode 6408, and a second output 6410 electrically coupled to the base 6402. The electrical coupling between the drive signal source 6410, and the electrode-mirror 6408 preferably comprises a wire bonded wire. The drive signal source 6410 outputs a voltage that establishes a field across the piezoelectric accommodating buffer layer 6404 for the purpose of controlling its height. By controlling the height of the piezoelectric accommodating buffer layer, the vertical position of the mirror electrode 6408 is varied. Gold is a suitable material for the mirror-electrode 6408 for use in the near infra-red, whereas aluminum is suitable for visible. The electrode-mirror 6408 is preferably deposited by sputtering, although evaporation, or chemical vapor deposition can also be used.

FIG. 65 shows a Michelson interferometer system 6500 in which the second tunable mirror 6400 is used. The system 6500 includes an optical radiation source 6502. The optical radiation source 6502 is preferably a laser such as optical laser 180 (FIG. 32). The optical radiation source 6502 directs a beam of optical radiation at a partially transmitting reflector 6504. The partially transmitting reflector 6504 is arranged at 45 degrees with respect to the beam. A beam reflected from the partially transmitting reflector 6504 is retro-reflected by a fixed mirror 6506 forming a first retro-reflected beam. A portion of the first retro-reflected beam is transmitted through the partially transmitting reflector 6504 to an exit aperture 6508. A portion of the beam from the optical radiation source 6502 is initially transmitted through the partially transmitting reflector 6504, and is retro-reflected by the mirror-electrode 6408 of the second tunable mirror 6400 forming a second retro-reflected beam. A portion of the second retro-reflected beam is reflected by the partially transmitting reflector 6504 and interferes with the portion of the first retro-reflected beam that is transmitted by the partially transmitting mirror 6504 at the exit aperture 6508. By adjusting the height of the mirror-electrode 6408, the portions of the first and second retro-reflected beams appearing at the exit aperture 6508 can be made to destructively or constructively interfere to a greater or lesser degree. This system 6500 can be used for example for modulating the optical radiation coupled from the optical radiation source 6502 through the exit aperture 6508.

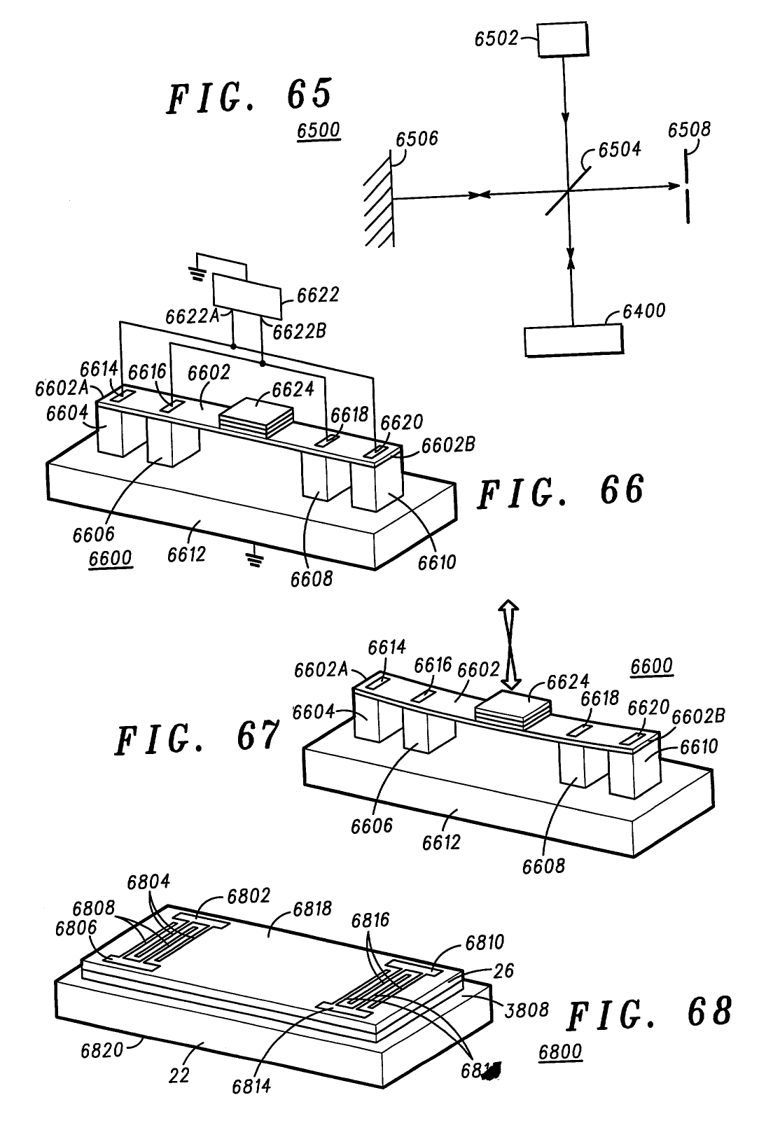

FIG. 66 is a perspective view of a third tunable mirror 6600. The third tunable mirror 6600 comprises a beam 6602 etched out of the monocrystalline material layer 26, and a base 6612 made from the monocrystalline substrate 22. The beam 6602 preferably comprises a III-V compound semiconductor. The base can also include the amorphous intermediate layer 28. The beam 6602 is supported on the base by first 6604, second 6606, third 6608, and fourth 6610 pedestals fabricated from the piezoelectrically active accommodating buffer layer 3808 (FIG. 38). The lower part of the pedestals may include the amorphous intermediate layer 28. The first through fourth pedestals 6604-6610 are arranged in a line. The first 6604 and the second 6606 are located close together near the left end 6602A of the beam 6602, and the third 6608 and fourth 6610 pedestals are located close together near the right end 6602B end of the beam 6602. The piezoelectric material included in the first through fourth pedestals 6604-6610 is polarized vertically, i.e., perpendicularly to the base 6612. The polarization vector can be up or down. The four pedestals 6604-6610 serve as piezoelectric transducers.

An optical multilayer stack 6624 that is also formed from the monocrystalline material layer 26 is located on the beam 6602 centered between the left 6602A and right 6602B ends. The optical multilayer stack 6624 preferably comprises alternating layers of Gallium arsenide and Aluminum Gallium arsenide.

A first electrode 6614 is located on the beam 6602 over the first pedestal 6604. A second electrode 6616 is located on the beam 6602 over the second pedestal 6606. A third electrode 6618 is located on the beam 6602 over the third pedestal 6608. A fourth electrode 6620 is located on the beam 6602 over the fourth pedestal 6610. The first through fourth electrodes 6614-6620 are used to apply electric fields to the pedestals 6604-6610 in order to selectively cause the pedestals 6604-6610 to increase or decrease in height. The first 6614 and fourth 6620 electrodes are electrically coupled to a first output 6622A of a reversible polarity bipolar drive signal source 6622. The second 6616 and third 6618 electrodes are electrically coupled to a second output 6622B of the bipolar drive signal source 6622. The base 6612 is grounded.

In operation the drive signal source 6622 outputs a first voltage (referenced to ground) at the first output 6622A, and a second voltage (referenced to ground) at the second output 6622B. The voltages are coupled to four electrodes 6614-6620 from the drive signal source 6622. The voltages are associated with electric fields that pass between the electrodes 6614-6620 and the monocrystalline substrate 6612. The height of each pedestal 6604-6610 can be increased by applying an electric field that is parallel to its polarization and decrease by applying an electric field that is anti-parallel to its polarization. By outputting a first and second voltages of opposite polarity, the beam 6602 can be made to assume a bowed shape. For example if the pedestals 6604-6610 have a polarization vector that points downward perpendicularly to the base 6612, and a positive voltage is output at the first output 6622A and consequently appears at the first 6614 and fourth 6620 electrodes, the first and fourth pedestals 6604, 6610 will increase in height. If at the same time, a negative voltage is output at the second output 6622B and consequently appears at the second 6616 and third 6618 electrodes, the second 6606 and third 6608 pedestals will decrease in height. The increase in height of the first and fourth pedestals 6604, 6610 accompanied by the decrease in height of the second and third pedestals 6606, 6608 will cause the beam 6602 to assume a downward bowed shape as depicted in FIG. 67. The two-headed arrow in FIG. 67 indicates an axis of movement of the mirror 6624. By reversing the voltages output by the drive signal source 6622, the beam 6602 can be made to assume a upward bowed shape. By controlling the height of the mirror 6624, the height of an air layer 6626 below the beam 6602, underneath the mirror 6624 can be controlled. The height of the air layer 6626 contributes along with heights and indexes of refraction of the layers of the mirror 6624 and the base 6612 to determining the spectrally dependent reflection and transmission properties for the tunable mirror 6600. By employing four pedestals 6004-6010 as described above a large range of adjustment of the height of the air layer can be achieved.

According to an alternative embodiment of the invention, the multilayer stack 624 is replaced with a metallic reflector.

FIG. 68 is a perspective view of a surface acoustic wave device (SAW) 6800. The SAW device 6800 can be fabricating using the monocrystalline substrate 22, and a piezoelectrically active accommodating buffer layer 3808 of semiconductor structure 20 (FIG. 38).

The SAW device 6800 comprises a piezoelectric slab 6818 made from the piezoelectrically active accommodating buffer layer 3808 (FIG. 38). For use in constructing the SAW device 6800 the accommodating buffer layer is made from a material that exhibits the piezoelectric effect. The piezoelectric slab 6818 is supported on a base 6820 that preferably includes the monocrystalline substrate 22, and the amorphous buffer layer 28. The piezoelectric slab6 6818 serves as a piezoelectric transducer.

A first 6802, a second 6806, a third 6810, and a fourth 6814 transducer electrodes are located on the piezoelectric slab 6818. The first through fourth electrodes 6802, 6806, 6810, 6814 are preferably formed by selectively doping the monocrystalline material layer 26. Alternatively, the first through fourth electrodes 6802, 6806, 6812, 6814 are formed by depositing metal. The first electrode 6802 includes a first plurality of fingers 6804. The second electrode 6806 includes a second plurality of fingers 6808 that are interdigitated with the first plurality of fingers 6804. By applying a sinusoidal voltage between the first 6802 and second 6806 electrodes a surface acoustic wave can be launched in the piezoelectric slab 6818. A part of the energy of the surface acoustic wave may propagate in the base 6820. The third electrode 6810 includes a third plurality of fingers 6812, and the fourth electrode 6814 includes a fourth plurality of fingers 6816 that are interdigitated with the third plurality of fingers 6812. When the surface acoustic wave reaches the interdigitated third and fourth pluralities of fingers 6812, 6816 it will induce a voltage between the third 6810 and fourth 6814 electrodes. The spacing of the fingers in terms of the wavelength of surface acoustic waves determines the operating frequency of the SAW device 6800. The SAW device 6800 as shown, is configured as a two port filter. Other SAW device configurations can also be implemented using a semiconductor structure such as shown in FIG. 1 that includes the piezoelectrically active accommodating buffer layer 3808 (FIG. 38).

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A microelectromechanical device comprising:
a monocrystalline substrate;
a piezoelectric material selected from the group consisting of alkaline earth titanates, zirconates, hafnates, niobates, tantalates, and the tin-based perovskites overlying the monocrystalline substrate; and
one or more electrodes proximate the piezoelectric material for applying one or more piezoelectric action inducing electric fields to the perovskite material.

2. The microelectromechanical device according to claim 1 wherein the monocrystalline substrate comprises:
a diamond lattice crystal of a material selected from the group consisting of silicon, germanium, mixed silicon and germanium, mixed silicon and carbon, mixed silicon, and germanium and carbon.

3. The microelectromechanical device according to claim 2 further comprising:
an amorphous oxide material that is interposed between the monocrystalline substrate and the piezoelectric material and is in direct contact with the monocrystalline substrate and the piezoelectric material.

4. The microelectromechanical device according to claim 2 wherein the monocrystalline substrate comprises:
a monocrystalline silicon.

5. The microelectromechanical device according to claim 1 further comprising:
a semiconductor material layer overlying the piezoelectric material.

6. The microelectromechanical device according to claim 5 wherein:
the perovskite material includes:
one or more edge walls bounding a gap in the piezoelectric material;
the semiconductor material layer includes:
a bridge including:
a first end overlying the piezoelectric material;
a second end overlying the piezoelectric material; and
a middle portion extending across the gap; and
the one or more electrodes include:
a first electrode overlying the first end of the bridge.

7. The microelectromechanical device according to claim 6 wherein the one or more electrodes further comprise:
a second electrode overlying the second end of the bridge.

8. The microelectromechanical device according to claim 6 wherein: the semiconductor material layer comprises a compound semiconductor.

9. The microelectromechanical device according to claim 5 wherein:
the piezoelectric material comprises:
a first pedestal formed out of the piezoelectric material;
a second pedestal formed out of the piezoelectric material;
a third pedestal that is located between the first pedestal, and the second pedestal and is formed out of the piezoelectric material; and
a fourth pedestal that is located between the second pedestal and the third pedestal and is formed out of the piezoelectric material;
the semiconductor material layer comprises:
a bridge of semiconductor material spanning between the first pedestal and second pedestal, and over the third pedestal and the fourth pedestal; and
the one or more electrodes comprises:
a first electrode located on the bridge over the first pedestal;
a second electrode located on the bridge over the second pedestal;
a third electrode located on the bridge over the third pedestal; and
a fourth electrode located on the bridge over the fourth pedestal.

10. The microelectromechanical device according to claim 9 wherein the semiconductor material layer further comprises:
a multilayer interference film.

11. The microelectromechanical device according to claim 9 further comprising:
a mirror supported on the bridge of semiconductor material between the second pedestal and the third pedestal.

12. The microelectromechanical device according to claim 1 wherein:
the piezoelectric material includes:
an upper surface;
a lower surface; and
a first cantilevered beam shaped portion including:
a clamped end that is supported on the monocrystalline substrate; and
a free end.

13. The microelectromechanical device according to claim 12 wherein:
the one or more electrodes include:
a first electrode located proximate the clamped end; and
a second electrode located proximate the free end.

14. The microelectromechanical device according to claim 13 wherein:
the first cantilevered beam shaped portion is polarized in a direction approximately parallel to a longitudinal axis of the cantilevered beam shaped portion.

15. The micromechanical device according to claim 13 further comprising:
a conductor extending from the clamped end to the second electrode.

16. The microelectromechanical device according to claim 12 wherein:
the monocrystalline substrate comprises one or more edges defining an opening through the monocrystalline layer aligned with the first cantilevered beam shaped portion.

17. The microelectromechanical device according to claim 16 further comprising:
a cantilevered beam shaped portion of semiconductor material overlying the first cantilevered beam shaped portion proximate the upper surface.

18. The microelectromechanical device according to claim 17 wherein the one or more electrodes comprise:
an electrode adjacent to the second surface.

19. The microelectromechanical device according to claim 18 further comprising:
a via that extends through the monocrystalline substrate and is electrically coupled to the electrode adjacent to the second surface.

20. The microelectromechanical device according to claim 1 further comprising:
an optical component mechanically coupled to the piezoelectric material.

21. The microelectromechanical device according to claim 20 wherein:
the optical component comprises a reflector.

22. The microelectromechanical device according to claim 20 wherein:
optical component comprise comprises a multilayer interference film formed on piezoelectric material.

23. The microelectromechanical device according to claim 22 wherein:
the multilayer interference film comprises a plurality of layers of III-V type semiconductor.

24. The microelectromechanical device according to claim 22 wherein:
the piezoelectric material comprises one or more edges bounding a gap in the piezoelectric material underlying the first multilayer interference film.

25. The microelectromechanical device according to claim 1 wherein the one or more electrodes comprise:
a first electrode including a first plurality of fingers; and
a second electrode including a second plurality of fingers that are interdigitated with the first plurality of fingers.

26. The microelectromechanical device according to claim 25 further comprising:
a third electrode that includes a third plurality of fingers and is located in spaced relation to the first electrode and the second electrode on the piezoelectric material; and
a fourth electrode including a fourth plurality of fingers that are interdigitatated with the third plurality of fingers.

27. A method of fabricating a piezoelectric device, the method comprising the steps of:
obtaining a diamond lattice monocrystalline substrate;
growing a piezoelectric layer including a material selected from the group consisting of alkaline earth titanates, zirconates, hafnates, niobates, tantalates, and the tin-based perovskites over the monocrystalline substrate;
etching the piezoelectric layer to define a piezoelectric transducer;
forming one or more electrodes proximate the piezoelectric transducer; and
polarizing the piezoelectric transducer.

28. The method of claim 27 wherein the step of growing a piezoelectric layer comprises the sub-step of:
growing a piezoelectric layer that is substantially lattice matched to the diamond lattice monocrystalline substrate over the monocrystalline substrate.

29. The method according to claim 27 wherein the step of growing the piezoelectric layer includes the step of:
concurrently growing an amorphous interface layer between the diamond lattice monocrystalline substrate and the piezoelectric layer.

30. The method according to claim 27 further comprising the step of:
forming a crystalline template layer that chemically bonds to the piezoelectric layer on the piezoelectric layer; and
forming a semiconductor material layer that chemically bonds to the crystalline template layer on the template layer.

31. The method according to claim 30 further comprising the step of:
etching the semiconductor material layer to define one or more semiconductor material parts of the piezoelectric device.

32. The method according to claim 31 wherein the step of etching the semiconductor material layer comprises the step of:
etching the semiconductor material layer to define a beam including a first, second end, and a midsection.

33. The method according to claim 32 further comprising the step of:
etching a portion of the piezoelectric layer out from under the midsection of the beam, whereby a beam that is suspended at at least two ends on the piezoelectric layer is obtained.

34. The method according to claim 33 wherein the step of forming one or more electrodes comprises the sub-step of:
forming a first electrical contact proximate the first end of the beam.

35. The method according to claim 34 wherein the step of forming one or more electrodes further comprises the sub-step of:
forming a second electrical contact proximate the second end of the beam.

36. The method according to claim 35 further comprising the step of:
forming a mirror on the midsection of the beam.

37. The method according to claim 36 wherein the step of forming a mirror comprises the sub-step of:
depositing a stack of monocrystalline material layers characterized by a plurality of refractive indexes on the midsection of the beam.

38. The method according to claim 27 wherein the step of forming one or more electrodes comprises the sub-steps of:
depositing a monocrystalline semiconductor layer on the piezoelectric layer; and
doping the monocrystalline semiconductor layer.

39. The method according to claim 38 wherein the step of doping the monocrystalline layer comprises the sub-step of:
doping the monocrystalline semiconductor layer to define a first electrode that includes a first plurality of fingers, and a second electrode that includes a second plurality of fingers that are interdigitated with the first plurality of fingers.

40. The method according to claim 27 further comprising the step of:
etching an opening through the monocrystalline substrate up to the piezoelectric layer.

41. The method according to claim 40 wherein the step of etching the piezoelectric perovskite layer comprises the sub-step of:
etching the piezolelectric layer over the opening to define a cantilevered beam.

42. The method according to claim 41 further wherein the step of forming one or more electrodes comprises the sub-step of:
depositing a lower electrode through the opening onto the piezoelectric layer

43. The method according to claim 41 further comprising the step of:
forming a via through the monocrystalline substrate to the lower electrode.

44. The method according to claim 41 further comprising the steps of:
depositing a semiconductor material layer over the piezoelectric layer; and
etching the semiconductor material layer to form an upper layer of the cantilevered beam.

45. The method according to claim 44 wherein the step of forming one or more electrodes comprises the sub-step of:
forming one or more electrical contacts on the upper layer of the cantilevered beam.
